(19) United States
(12) Patent Application Publication
(10) Pub. No.: US 2013/0263606 A1
(43) Pub. Date: Oct. 10, 2013

(54) CURRENT LEAD DEVICE

(71) Applicant: Sataro Yamaguchi, Aichi (JP)

(72) Inventor: Sataro Yamaguchi, Aichi (JP)

(73) Assignee: CHUBU UNIVERSITY EDUCATIONAL FOUNDATION, Kasugai-shi, Aichi (JP)

(21) Appl. No.: 13/878,687

(22) PCT Filed: Oct. 14, 2011
(86) PCT No.: PCT/JP2011/073717

§ 371 Date: Jun. 13, 2013

(30) Foreign Application Priority Data
Oct. 14, 2010 (JP) 2010-231989

(51) Int. Cl. H05K 7/20

(52) U.S. Cl. CPC H05K 7/20
USPC 62/3.2; 62/259.2

(57) ABSTRACT

A current lead apparatus includes a pipe surrounding a current lead connected between a low temperature side terminal and an ambient side terminal. The refrigerant gas discharged at the ambient temperature side is circulated via a plurality of stages of freezers to a low temperature side of the pipe.

### FIELD

### CROSS-REFERENCE TO RELATED APPLICATION

This invention claims priority rights pertaining to the JP Patent Application 2010-231989 filed in Japan on Oct. 14, 2010. The total contents of this JP Patent Application of the senior filing date are to be incorporated by reference in the present Application.

This invention relates to a current lead for superconduction.

### BACKGROUND

To cope with heat intrusion into a current lead that interconnects an ambient side terminal and a low temperature side terminal connected to a superconductive line, the present inventor has conducted researches for reducing the amount of heat intrusion using a Peltier current lead (PCL). As regards this sort of the current lead, reference is made in particular to Patent Literatures recited hereinbelow.

There is still a demand for further reducing the heat intrusion into the current lead.

FIG. 1 illustrates a current lead in a related technique. A copper wire (current lead) connects an ambient temperature end (300K) and a low temperature end (77K).

Since heat is caused to flow by a temperature gradient, the ohmic heat generation in the copper lead all enters the 77K low temperature end.

If the cross-section of the copper wire is thicker or the wire length is shorter, the ohmic heat generated by the current is decreased. However, the heat intrusion to the low temperature side by heat conduction is increased.

If the cross-section of the copper wire is made smaller or the wire length is made shorter, the current induced ohmic heat generation is decreased. However, the heat intrusion due to heat conduction is increased.

Hence, there should be optimum values of the wire length and the wire cross-section.

Thus, in the designing of the current lead, it is necessary to solve an equation for a heat flux to find an optimum solution. With this in view, the present inventors developed software and publicized several treatises.

[Patent Literature 1] JP Patent Kokai JP-A-08-236342

[Patent Literature 2] JP Patent Kokai JP-A-2003-51625

[Patent Literature 3] JP Patent Kokai J-A-2003-46150

[Patent Literature 4] JP Patent Kokai JP-A-2004-6859

[Patent Literature 5] JP Patent Kokai JP-A-2003-217735

[Non-Patent Literature 1] L. Bromberg et al., “Current Lead Optimization for Cryogenic Operation at Intermediate Temperature”, PSFC/JA-09-23, MIT Plasma Science and Fusion Center, Sep. 22, 2009,

[Non-Patent Literature 2] Internet<URL: http://www.sankikeiso.co.jp/TechnicalInformation/Informationrefrigeratingcycle.html>

### SUMMARY

The entirety of the contents disclosed in the above mentioned Patent Publications 1 to 5 and the Non-Patent literature 1 is incorporated herein by reference.

The following is an analysis of the related technique.

By way of an optimum solution for FIG. 1, there is shown in FIG. 2 the temperature distribution with respect to the longitudinal direction of a lead. In FIG. 3 the heat flux with respect to the same direction is shown. In FIG. 2, the horizontal axis denotes a normalized length of a copper lead and the vertical axis denotes the temperature [K]. In FIG. 3, the horizontal axis denotes the normalized length of a copper lead and the vertical axis denotes the heat flux [W]. Here, the current value is set at 100A, and the lead length is normalized so that it is zero at the 77K side as a point of origin, with the length corresponding to 300K being 1 (unity). When the temperature approaches to 300K, the differential coefficient of the temperature distribution approaches zero. This minimizes heat intrusion due to heat conduction from outside. When the current is caused to flow through the copper lead, there is generated heat, which heat in its entirety flows to the low temperature side due to the temperature gradient, as indicated in FIG. 3.

Hence, a heat flux on the low temperature side increases, and the sum of the heat intrusion on the ambient temperature side and heat generated in the overall current lead thus represents heat load on a 77K freezer.

According to the results of optimum designing, the amount of heat intrusion per current is Q₀=42.5 W/kA. However, a design value, ordinarily used, is 50 W/kA. Thus, for the current of 1 kA, heat intrusion to 77K is 50 W (42.5 W). Assuming that the coefficient of performance (COP), the cooling/heating capacity per 1 W, of an improved freezer at 77K is 0.1, and the heat is to be transferred to the ambient temperature side, the power of 50/0.1=500[W] is consumed. It is noted that, for a Stirling freezer with the COP of 0.067, manufactured by AISIN SEIKI Co., Ltd., the power of 50/0.067=746[W] is consumed.

It is therefore an object of the present invention to provide a current lead in which heat intrusion to a low temperature side may be reduced.

According to the present invention, there is provided a current lead in which a refrigerant gas is caused to flow for heat exchange from a low temperature side to a high temperature side of a pipe surrounding a current lead connected between a low temperature side terminal and an ambient temperature side terminal, and in which the refrigerant gas discharged on the ambient temperature side is circulated via a plurality of freezer stages to the low temperature side of the pipe.

According to the present invention, the current lead includes a

Peltier element(s) on the ambient temperature side or on both the ambient temperature side and the low temperature side. The Peltier element(s) absorbs heat by being passed through by the current.

According to the present invention, heat intrusion to a low temperature side may be reduced.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF DRAWINGS

FIG. 1 is a schematic diagram illustrating a configuration of a current lead according to the related technique.

FIG. 2 is a graph showing the temperature distribution versus lead length relationship.

FIG. 3 is a graph showing the heat flux distribution versus lead length relationship.

FIG. 4 is a schematic diagram illustrating a configuration of a double stage current lead according to the related technique.

FIG. 5 is a graph showing the heat flux of the copper lead versus temperature relationship.

FIG. 6 is a schematic diagram illustrating a configuration of a three stage current lead.

FIG. 7 is a schematic diagram illustrating an example (gas heat exchanger type three stage current lead) of an exemplary embodiment of the present invention.

FIG. 8 is a schematic diagram illustrating an example (gas heat exchanger type double stage Peltier current lead) of an exemplary embodiment of the present invention.

FIG. 9 is a schematic view for illustrating the principle of a freezer.

FIG. 10 is a schematic diagram illustrating an example (current lead built-in type freezer) of an exemplary embodiment of the present invention.

FIG. 11 is a schematic diagram illustrating a configuration of a multi-stage Brayton cycle freezer (parallel type) of the related technique.

FIG. 12 is a schematic view for illustrating an example (building into a current lead of a multi-stage Brayton cycle freezer) of an exemplary embodiment of the present invention.

FIG. 13 is a schematic diagram illustrating an example (Peltier current lead with a built-in freezer) of an exemplary embodiment of the present invention.

### PREFERRED MODES

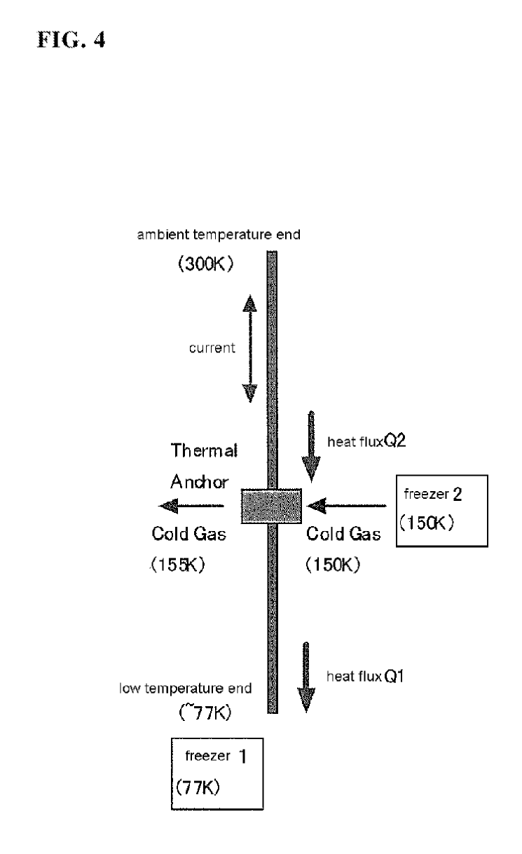

In the explanation to follow, presuppositions and preferred modes of the present invention will be explained in this order. Investigations into a multi-stage current lead are now being conducted by a number of teams, including Minervini, of MIT (Massachusetts Institute of Technology). FIG. 4 shows a structure currently searched (Non-Patent Literature 1). This is such a system in which there is installed halfway on a current lead a thermal anchor (TA) through which a freezer gas (liquid) is circulated. In the present example, the TA is at 150K and supplied with a gas at 150K from another freezer. The gas having a temperature slightly increased is circulated in the TA and again cooled by the freezer to maintain a constant temperature. In such structure, any heat intrusion from a temperature side higher than in the TA is absorbed in its entirety by this TA, and represents a heat load for the freezer 2.

The heat intrusion by the ohmic heat generated at the portion of the current lead where the temperature is lower than the above mentioned temperature represents a heat load on the 77K freezer. Hence, the heat load on the 77K freezer is decreased.

If the temperature is lowered, the electrical resistance of copper is lowered, and hence the heat generation at 150K or lower is appreciably smaller than that at 300K or lower.

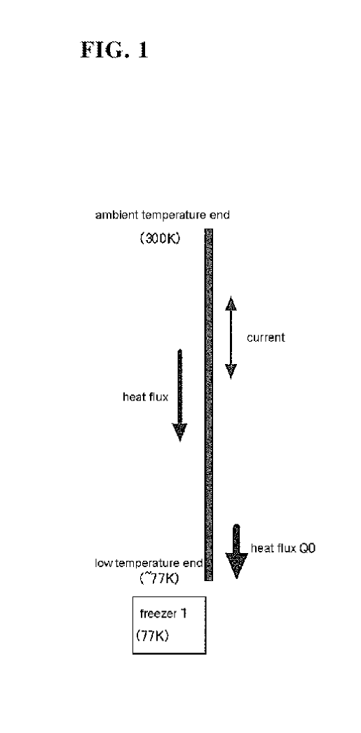

On the other hand, an amount of heat intrusion Q2 to 150K, an amount of heat intrusion Q1 to 77K and an amount of heat intrusion Q0 to 77K in FIG. 1 are related to one another by

Q0=Q1+Q2

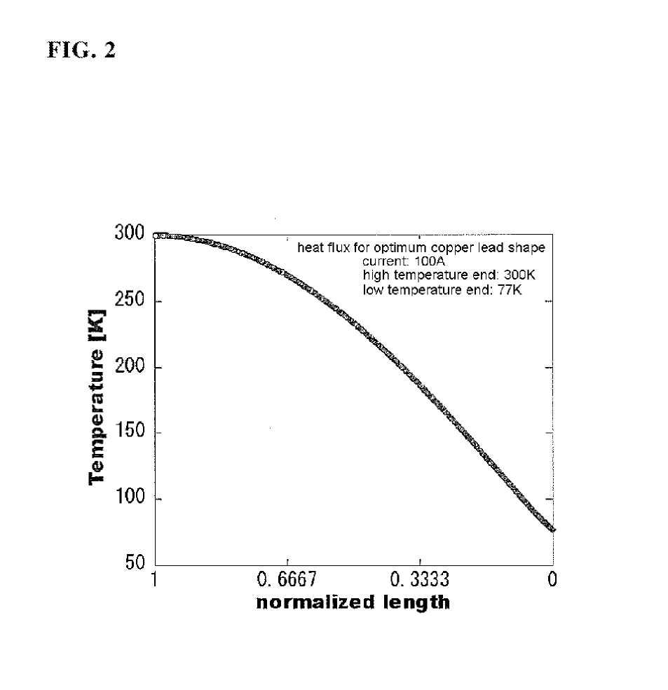

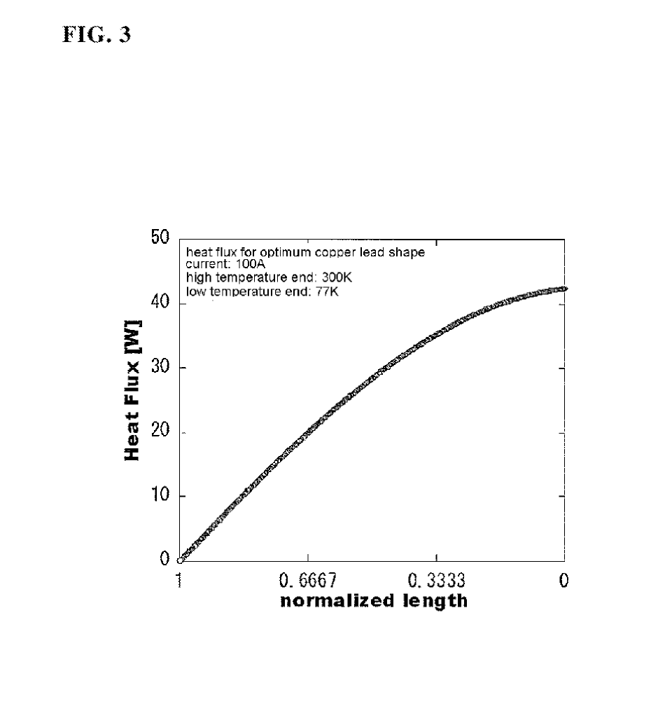

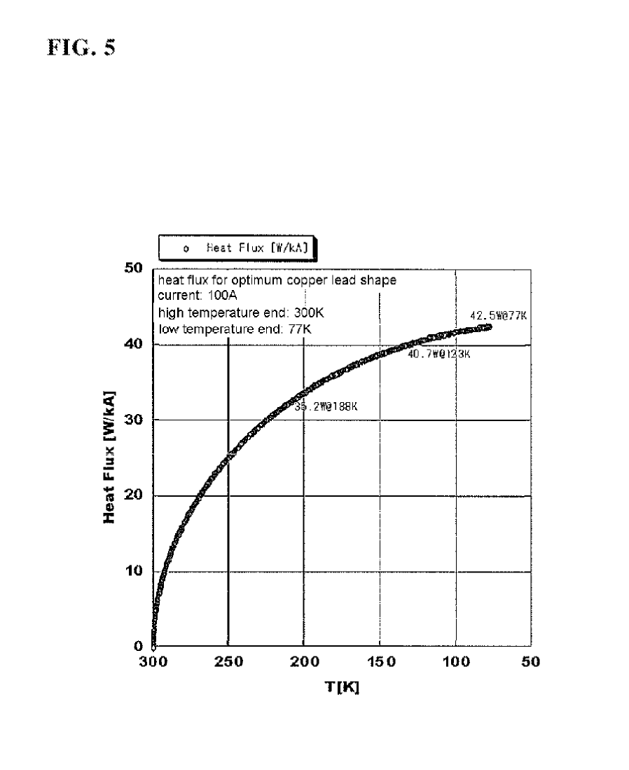

Although the sum of heat loads absorbed by the two freezers is unchanged, the COP of a freezer having a higher freezing temperature is larger. Hence, the sum of the power consumptions of the two freezers is decreased. This effect is now really estimated. The relationship between the heat flux in the current lead and the temperature is shown in FIG. 5, in which the horizontal axis denotes the temperature and the vertical axis the heat flux. FIG. 5 is obtained by rewriting data in FIGS. 2 and 3. In FIG. 5, the heat flux per current for 77K is 42.5 W/kA, and that for 123K is 40.7 W/kA.

Thus, with the current of 1 kA, the heat load on the freezer 1 is 1.8 (=42.5−40.7)W, while that on the freezer 2 is 40.7 W. The COP of the freezer differs with temperature, such that, if the temperature is higher, the COP is greater.

For example, a freezer model number MDF-1156AT (manufactured by SANYO Electric Co., Ltd.) is able to cool down to −152° C. (=123K), with COP=0.221. A model number MDF-793 is able to cool down to −85° C. (=188K), with COP=0.75. Thus, heat fluxes at these different temperatures are shown in FIG. 5.

Referring to FIG. 4, the temperature of the thermal anchor (TA) is set at 150K. Two cases (a case with TA temperature of 123K and a case with TA temperature of 188K) will now be scrutinized.

Case 1 (case of TA Temperature=123K)

As presuppositions, the freezer that cools down to 77K is a Stirling freezer, with COP=0.067. It is seen from FIG. 5 that the heat flux down to 123K is 40.7 W. Hence, the power necessary to transfer this heat flux up to the ambient temperature is 40.7/0.221=184.2 W.

On the other hand, since the heat load to 77K is 1.8 W, the power consumption for this freezer is 1.8/0.067=26.9 W. Hence, a sum total of 211.1 W of power is consumed.

If cooling down is performed only by the 77K freezer (a single stage cooling), the power consumed is 42.5/0.067=634.4 W. The power consumption of 211.1 W for the case of FIG. 4 is approximately one-third of 634.4 W which is a value for single-stage cooling.

### Case 2 (With TA Temperature=188K)

Since the heat flux down to 188K is 35.2 W, the power necessary to transfer heat up to the ambient temperature is 35.2/0.75=46.9 W

On the other hand, since the heat load to 77K is 7.3 W, the power consumption for this freezer is 7.3/0.067=109 W. Hence, a sum total of 155.6 W of power is consumed. That is, the power consumption is decreased to approximately 24.5% of that for the case of the single-stage cooling.

It may thus be expected that an increased number of stages is more beneficent to decrease the power consumption.

The following describes a three-stage configuration. That is, two thermal anchors (TAs) are provided at different portions on the current lead.

### <Exemplary Embodiment 1>

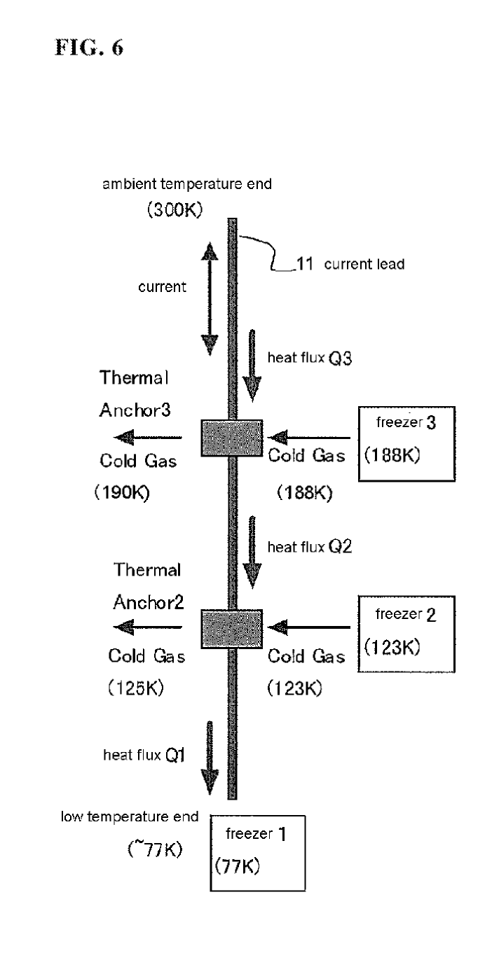

FIG. 6 illustrates a configuration of a three-stage current lead. That is, three freezers 1 to 3 are used. In this case, the heat load on the freezer 1 (77K) is 1.8 W, with the power consumption being 26.9 W. The heat load on the freezer 3 (188K) is 35.2 W, with the power consumption being 46.9 W.

The thermal load on the freezer 2 (123K) is 5.5 W, with the power consumption being 24.9 (=5.5/0.221)W. Accordingly, a sum total of the power consumptions is 98.7 W.

This corresponds to 15% of the power consumption consumed in transferring heat from the current lead to ambient temperature in the state of the arts.

In this manner, heat intrusion may effectively be reduced by a multi-stage configuration.

A gas-cooled current lead was first proposed during the 1970s and, for the first time, made it possible to use a superconducting magnet on an experimental laboratory level. The system proposed was such a one in which a liquid refrigerant, which cools a superconductive magnet or the like, is vaporized due to heat intrusion from the current lead, with the so generated gas flowing through the inside of the current lead so as to be discharged via an ambient temperature part to outside. It is thus necessary to supply the refrigerant at all times, and hence the current lead could not be used for a system, such as power transmission line, even though it could be used for experimental equipment.

However, if the gas is re-circulated for use of cooling, the system may be utilized as a steady-state system. Additionally, with this concept, the current lead becomes to have a higher electric potential, so that the

TA as a heat exchanger needs to be electrically insulated from the freezer and hence becomes complex in structure. However, such problem may be dealt with, in particular with a system with three or more stages.

### <Exemplary Embodiment 2>

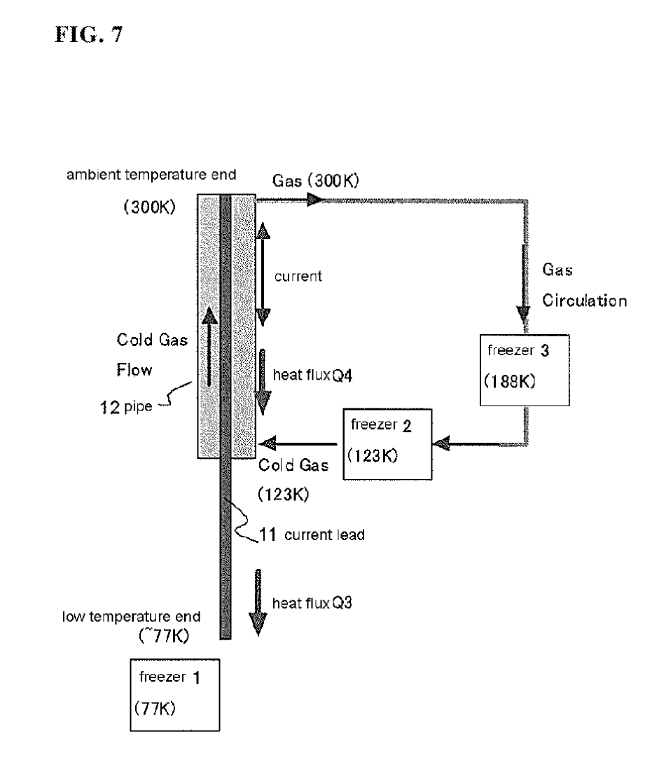

FIG. 7 shows a configuration of a gas heat exchanger type three stage current lead according to the present invention. Referring to FIG. 7, a refrigerant gas supplied from the freezer 2 flows through inside of a pipe 12 surrounding a current lead 11 from a low temperature side towards a high temperature side, with the refrigerant gas heat exchanged and discharged at ambient temperature (300K). It is then circulated on a path through the freezer 3 and then through the freezer 2. Then, in the freezer 3, electrical insulation at least is unneeded on a gas cooling path, while it is unnecessary to newly provide a thermal anchor (TA) in a high pressure current lead. Hence, the current lead may be simplified in structure. Moreover, the refrigerant gas is cooled after its temperature is raised to the ambient temperature, so that heat exchangers for the freezers 2 and 3 may be reduced in size. Thus, even though the amount of heat intrusion is equivalent to that of FIG. 6, the entire system may be facilitated from an engineering point of view.

It is another feature of the above described gas circulation system that the system may optimally be driven in keeping with the current by controlling the amount of gas circulation in keeping with the current.

It is common that though a voltage is kept constant, a current is changed in accordance with a load of the equipment. Hence, an amount of heat entering the low temperature side from the current lead is changed with a temperature. An optimum driving may be possible at all times by changing an amount of gas circulation.

### <Exemplary Embodiment 3>

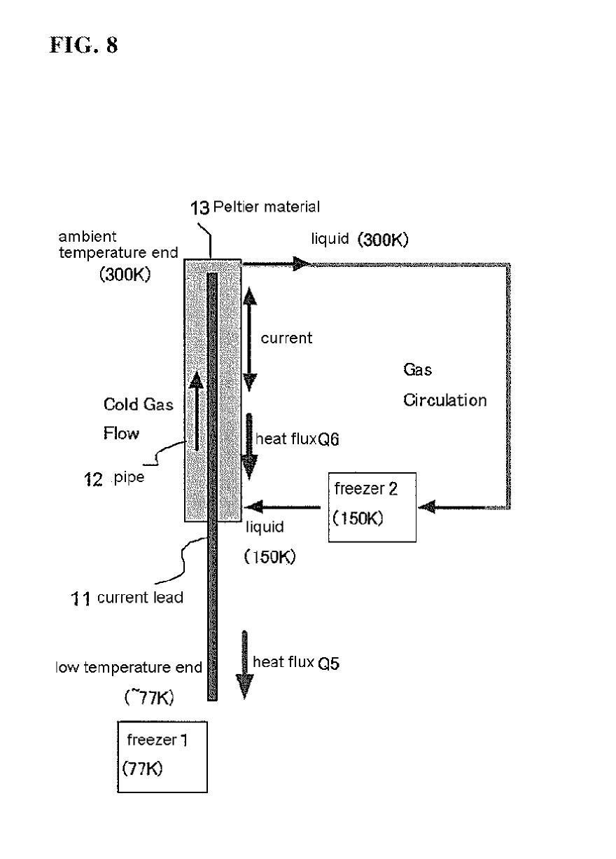

The present invention may be applied to a Peltier current lead (PCL). FIG. 8 shows its example (gas heat exchanger type double-stage Peltier current lead). A Peltier material 13 is arranged at an ambient temperature part of the current lead 11. There flows current through this material (Peltier material section) to reduce heat intrusion under the Peltier effect. A cooling gas is circulated through this system such that heat intrusion may be reduced by the Peltier current lead (PCL). Such a system that adjusts a flow rate of a circulating gas depending on a current value may be built in FIGS. 7 and 8 to control increase/decrease of an amount of the gas depending on the current value. This may improve the efficiency of the entire system.

In such case, the Peltier material 13 is made thin in thickness. However, a temperature difference of the order of 100K is produced. A probability is high that it becomes difficult for a gas to heat-exchange sufficiently in the Peltier material 13. To avoid such problem, it is preferred to liquefy a circulating gas, because a liquid is higher in the rate of heat transmission by nearly two orders of magnitude than a gas. More specifically, it would be a common practice to use a pressurized Freon-based or hydrocarbon-based refrigerant. In the structure shown in FIG. 4, there is not indicated a destination of the gas cooled to 150K (cold gas). That is, there is no description as to gas circulation in any treatises, including those by MIT, publicized to date. For this reason, circulation of the refrigerant gas is specified in more detail in FIGS. 7 and 8 in the present application. However, such circulation is carried out within the inside of the freezer itself.

### <Freezer>

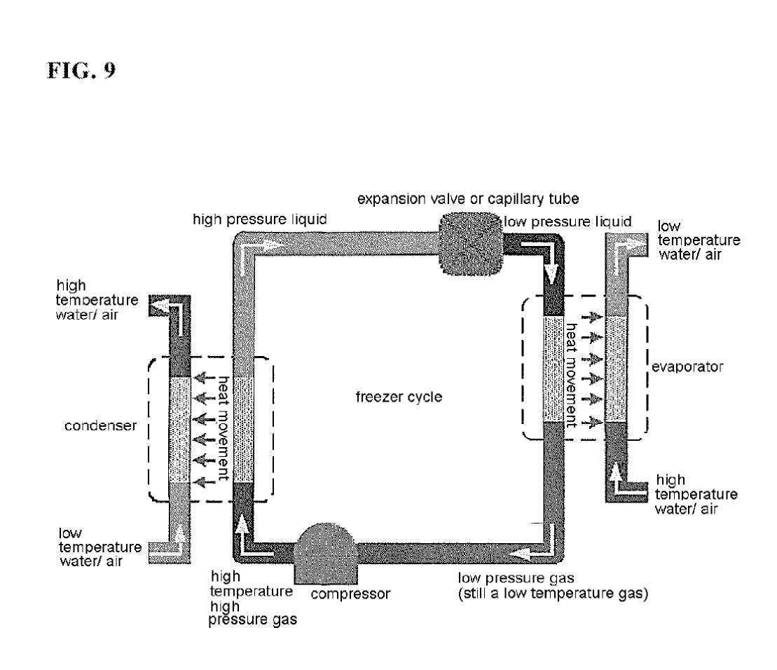

An example freezer used in the present invention will now be described. FIG. 9 illustrates the principle of a freezer of the related technique. The freezer is made up of a compressor, an expansion valve and two heat exchangers. The compressor generates a high temperature high pressure gas, which is then cooled to high pressure ambient temperature by the heat exchangers. The high pressure gas is then lowered in pressure by the expansion valve at the same time as it is lowered in temperature. This process, termed an equi-enthalpy process, is a process of adiabatic expansion. The gas, now lowered in temperature, cools an object for cooling via the heat exchangers. It should be noted that the direction of arrows indicated ‘heat transfer’ in FIG. 9 is reversed. The freezer explained suffers a problem that the low pressure gas, which exchanged heat on the low temperature side, and which is still low in temperature, is turned by the compressor into a high temperature high pressure gas. It would be desirable to use the gas until it is at an ambient temperature if such is possible. However, this would not conform to the role of the freezer. Thus, loss in energy will occur to degrade the efficiency of the freezer system. However, if FIGS. 7 and 8 are viewed from such perspective, an input to the freezer is an ambient temperature gas.

Thus, if the refrigerant circulating through the freezer is directly circulated through the current lead, the above mentioned problem is not presented, and hence the efficiency may be improved. In addition, since the heat exchangers used in the freezer may be dispensed with, heat exchanger loss may be decreased to improve the efficiency of the overall system.

### <Exemplary Embodiment 4>

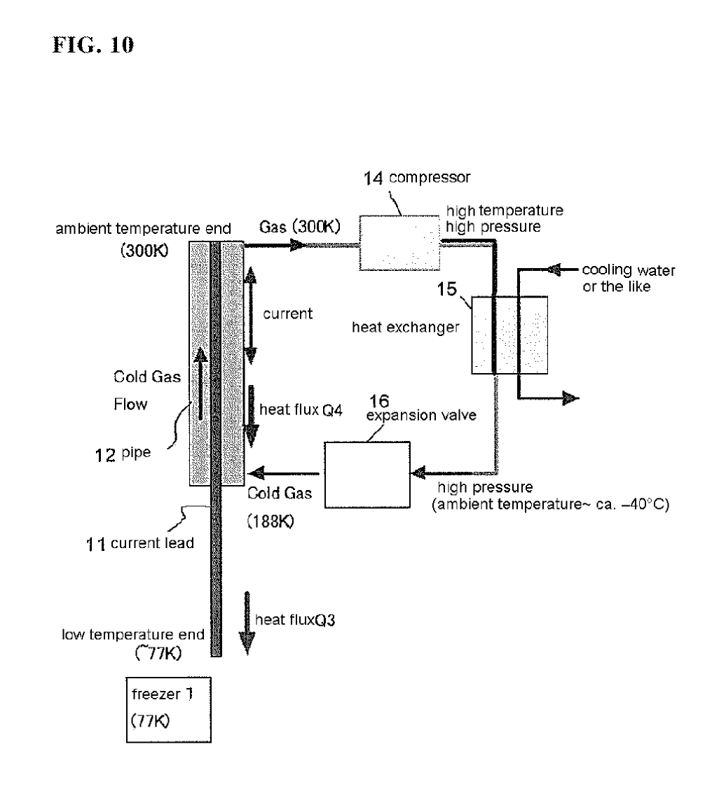

FIG. 10 shows an example of an exemplary embodiment 4 of the present invention. It is seen from FIG. 10 that a freezer itself is built in the current lead. That is, a heat exchanger 15 on a low temperature side also plays the role of a heat exchanger in a current lead 11. A refrigerant gas output from an ambient temperature end, is raised in temperature and pressure in a compressor 14 and lowered in temperature in the heat exchanger 15. The gas is turned in an expansion valve 16 into a low pressure low temperature gas which is thence supplied to a pipe 12 of the current lead 11. For example, if a high pressure ambient temperature gas from a high pressure nitrogen gas cylinder is supplied to a commercially available expansion valve called a JT (Joule-Thomson) valve, a low temperature gas at a temperature on the order of −120° C. may readily be generated. Therefore, such a compressor suffices that is used to store a nitrogen gas in a commercially available compressed nitrogen gas cylinder.

When a gas storage equipment, such as a gas reservoir, for example, a high pressure gas cylinder, not shown in FIG. 10, is provided between a heat exchanger and an expansion valve, and another reservoir is provided for a gas at an ambient temperature side end, it becomes unnecessary to run a compressor at all times. In such case, the entire system may be improved in operational reliability. It should be noted that, although the temperature of the gas entering the current lead is 188K in FIG. 10, it is actually determined as the COP of the freezer as well as heat intrusion into the current lead is taken into account. The expansion valve 16 may, of course, be fitted with a mechanism that exercises control by the current. That is, the amount of refrigerant circulation is changed in keeping with the heat flux that is varied with the current value. By so doing, the entire system may be improved in efficiently.

In the foregoing, the freezer 1 and the freezer for cooling the current lead are provided as separate apparatuses. Among high efficiency freezers, there is a multi-stage Brayton freezer.

### <Multi-Stage Brayton Freezer>

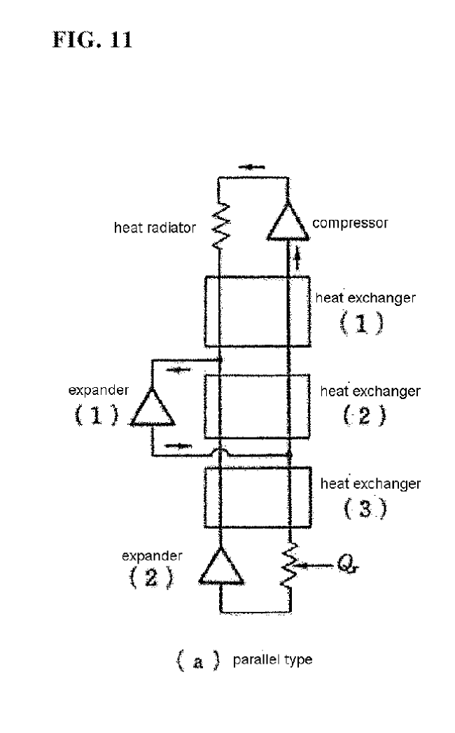

FIG. 11 illustrates an example multi-stage Brayton freezer. Specifically, FIG. 11 illustrates a type called a parallel type, where Qr is a heat exchanger part that absorbs heat at a low temperature. A heat radiator is also a heat exchanger. There are two expanders, one for low temperature and another for intermediate temperature, in order for optimization. In a freezer of extremely low temperature, the gas circulated after the heat Qr has been absorbed by a low temperature heat exchanger is still at a low temperature. Hence, the high pressure gas before expansion is cooled through heat exchangers (3), (2) and (1).

This improves the heat efficiency of the freezer. That is, in the present example, called a freezer, its internal configuration is such that heat exchange is carried out at a plurality of temperatures. Such configuration is ordinarily used for a freezer for a lower temperature.

### <Exemplary Embodiment 5>

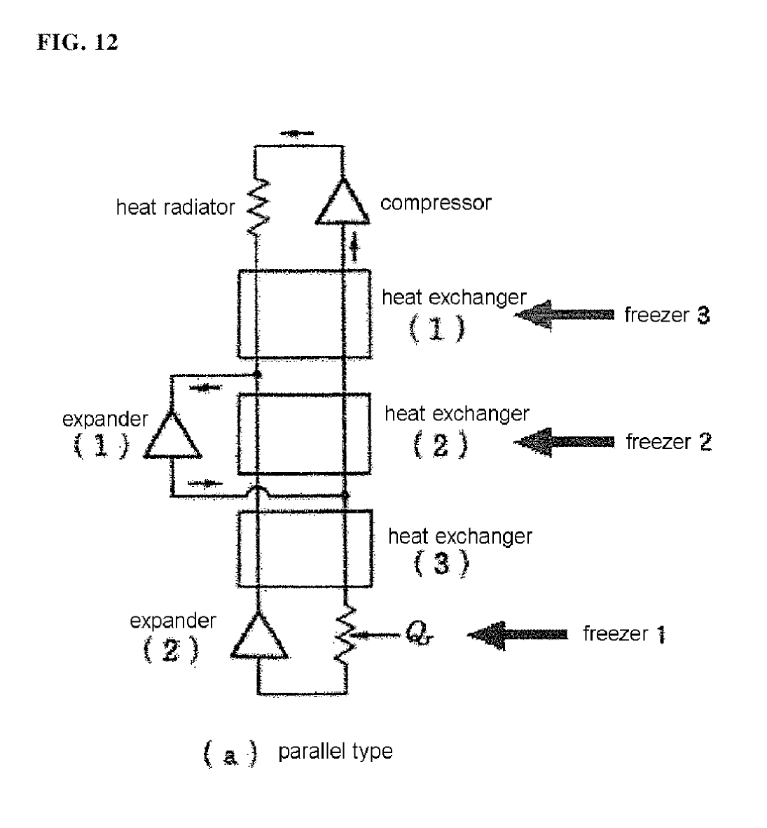

Thus, a freezer shown in FIG. 12 is proposed as exemplary embodiment 5 of the present invention. FIG. 12 is a diagram illustrating building a multi-stage Brayton cycle freezer into a current lead. An expander (2) cools down to the liquid nitrogen temperature to cool a system including a superconducting cable from a low temperature end of the current lead. That is, the expander corresponds to the freezer 1 of FIG. 6.

On the other hand, the heat exchanger (2) at an intermediate temperature and the heat exchanger (1) are designed to correspond to freezers 2 and 3, respectively. The heat exchangers are slightly increased in size, and the heat exchanger portions, thus increased in size, are designed to operate also as a freezer to cool an intermediate stage of the current lead, that is, a thermal anchor (TA). More specifically, a refrigerant is circulated between the thermal anchor (TA) of the current lead 11 and the heat exchanger.

As an alternative method, the working gas itself in the Brayton cycle freezer may be caused to flow directly into the thermal anchor (TA) of the current lead for circulation. In this case, a single freezer may can be used constitutionally for multiple freezers shown in FIG. 6.

As described above, in the heat exchanger (2), in which the amount of the low temperature gas is increased by the expander (1), heat absorption may be increased in the expander portion, resulting in engineering reasonableness.

The present exemplary embodiment is described with reference to an example of a parallel type Brayton cycle freezer. There may be used, however, a series type freezer and a freezer such as a multi-stage pre-cooling type Claude cycle freezer (Collins type freezer), exploiting a JT valve in addition to an expander.

### <Exemplary Embodiment 6>

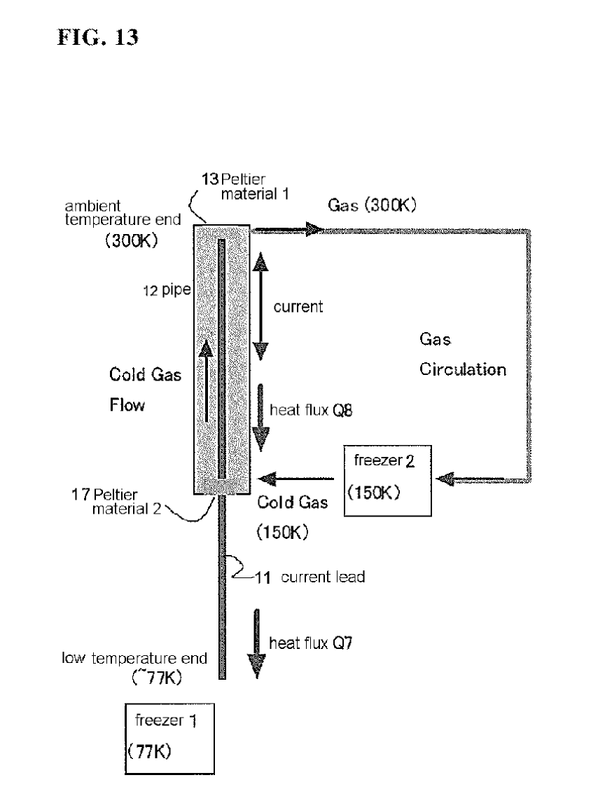

In an exemplary embodiment 6, BiSb with a high performance index at a lower temperature is used as a Peltier material which is improved in performance only at lower temperatures (Such a material exploiting super-lattice is known). With such configuration, optimum designing may be realized by changing the amount of the flowing gas. FIG. 13 is a diagram illustrating the configuration of the present exemplary embodiment. As shown in FIG. 13, a Peltier material 2 (17) is provided on the low temperature side of the current lead 11. Otherwise, the present exemplary embodiment is similar in configuration to FIG. 8. A Peltier material 1 (13) is provided at an ambient temperature side of the current lead 11.

The disclosures of the related Patent Publications are incorporated by reference herein. The particular exemplary embodiments or examples may be modified or adjusted within the gamut of the entire disclosure of the present invention, inclusive of claims, based on the fundamental technical concept of the invention. In addition, a variety of combinations or selection of elements inclusive of the elements of claims, exemplary embodiments or drawings, may be made within the concept of the claims. The present invention may encompass various modifications or corrections that may occur to those skilled in the art in accordance with the total disclosure and the technical concept inclusive of the claims and the technical concept of the invention.

1. A current lead apparatus comprising:
a current lead connected between a low temperature end and an ambient temperature end;
a pipe surrounding a part of the current lead along a longitudinal direction thereof, the pipe having one end provided at the ambient temperature end and having an opposite end elongated to a location of a pre-set temperature intermediate between the ambient temperature end and the low temperature end; and
at least one freezer built into the current lead apparatus, wherein
the freezer comprises:
a compressor;
a heat exchanger; and
an expander,
a refrigerant gas being caused to flow from the opposite end of the pipe through the pipe up to the one end of the pipe, the refrigerant gas discharged from the one end of the pipe being supplied to the compressor, the compressed gas being heat-exchanged by the heat exchanger and then expanded by the expander, the expanded gas being circulated either directly or via another freezer to the opposite end of the pipe.

2. The current lead apparatus according to claim 1, wherein the current lead includes
a Peltier element provided on the ambient temperature side of the current lead.

3. The current lead apparatus according to claim 1, wherein the current lead includes
first and second Peltier elements at locations corresponding to the one end and the opposite end along the longitudinal direction of the pipe.

4. (canceled)

5. The current lead apparatus according to claim 1, wherein each of the freezer stages is composed by a parallel type freezer including a compressor, a plurality of heat exchanger stages and a plurality of expanders.

6. (canceled)

7. A current lead apparatus comprising:
a current lead connected between a low temperature end and an ambient temperature end;
a pipe surrounding a part of the current lead along a longitudinal direction thereof, the pipe having one end provided at the ambient temperature end and having an opposite end elongated to a location of a pre-set temperature intermediate between the ambient temperature end and the low temperature end; and
at least one freezer built into the current lead apparatus,
a refrigerant gas being caused to flow from the opposite end of the pipe through the pipe up to the one end of the pipe, the refrigerant gas discharged from the one end of the pipe being supplied to the at least one freezer, the refrigerant gas cooled down by the at least one freezer being circulated to the opposite end of the pipe.

8. The current lead apparatus according to claim 7, wherein the current lead includes
a Peltier element provided on the ambient temperature side of the current lead.

9. The current lead apparatus according to claim 8, wherein in place of the refrigerant gas, a liquid is circulated through the pipe and the at least one freezer.
